(19) United States
(12) Patent Application Publication
(10) Pub. No.: US 2007/0254385 A1
(43) Pub. Date: Nov. 1, 2007

(54) Method of manufacturing light-emitting diode module

(75) Inventors: Ching-Huei Wu, San Chung City (TW); Jui-Tsung Liao, San Chung City (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/414,197

(22) Filed: May 1, 2006

(51) Int. Cl. H01L 21/66; H01L 21/00

(52) U.S. Cl. 438/14; 438/16; 438/17; 438/22

(57) ABSTRACT

A method of manufacturing a light-emitting diode module comprises the steps of: coupling an electronic device with a circuit board such that a distinguishing resistor is coupled adjacent to a light-emitting diode; baking the circuit board by a reflow oven; and testing the baked circuit board, whereby the related information of the light-emitting diode including the manufacturer, the product cycle, the product code, and the grade can be obtained via the distinguishing resistor. Accordingly, the marking accuracy will not be affected by the subsequent processes and the marking cost can also be reduced.

### FIELD OF THE INVENTION

The present invention relates to a method of manufacturing a light-emitting diode module with a convenient verification process and a reduced marking cost, and more particularly to a process for verifying an electronic device, for example, a light-emitting diode, mounted on a circuit board.

### BACKGROUND OF THE INVENTION

With the progress of technology, most persons nowadays own several electronic products on which electronic boards are unavoidably mounted. In the typical manufacturing process of a general electronic product, a circuit diagram is designed first. Next, several corresponding symbols of several electronic devices are printed on a circuit board in accordance with the circuit diagram. Next, the electronic devices can be coupled with the circuit board. Finally, a function test is performed on the circuit board to determine whether the circuit board is applicable to the electronic product.

However, in the above-mentioned process of printing the corresponding symbols of the electronic devices on the circuit board, the manufacturer must own a circuit board printer so as to print the related information including the bar code and the product code on the circuit board. Alternatively, several marking pasters can be pasted on the circuit board manually in the lack of the circuit board printer. However, these two marking methods have higher marking costs even if they can achieve the purpose of verification. In addition, the marking symbols printed by the circuit board printer are peeled off easily after a long period of use. Moreover, the marking pasters, which are pasted manually, are also peeled off easily and the wrong marking pasters may be pasted mistakenly because of the negligence of the worker.

In view of the foregoing problems, the present invention discloses a method of manufacturing a light-emitting diode to decrease the cost of marking and the error of marking.

### SUMMARY OF THE INVENTION

It is a main object of the present invention to provide a method of manufacturing a light-emitting diode for decreasing the cost and error of marking.

It is another object of the present invention to disclose a method of manufacturing a light-emitting diode that facilitates the quantity management, the quality control, and the problem tracking.

In order to achieve the above-mentioned object, a method of manufacturing a light-emitting diode module comprises the steps of: coupling an electronic device with a circuit board such that a distinguishing resistor is coupled adjacent to a light-emitting diode; baking the circuit board by a reflow oven; and testing the baked circuit board, whereby the related information of the light-emitting diode including the manufacturer, the product cycle, the product code, and the grade can be obtained via the distinguishing resistor. Accordingly, the marking accuracy will not be affected by the subsequent processes and the marking cost can also be reduced.

The aforementioned objects and advantages of the present invention will be readily clarified in the description of the preferred embodiments and the enclosed drawings of the present invention.

### BRIEF DESCRIPTION OF THE DRAWINGS

FIG. 1 is a flow diagram showing the manufacture process of the present invention.

FIG. 2 is a look-up table of a distinguishing resistor of the present invention.

### DETAILED DESCRIPTION OF THE PREFERRED EMBODIMENT

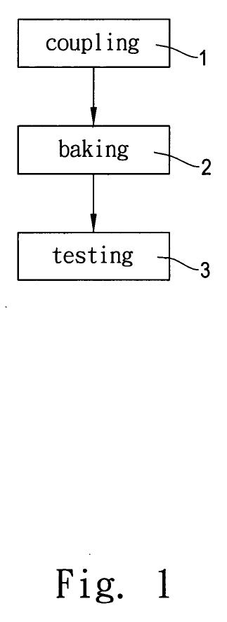

Referring to FIG. 1, the manufacturing method of the present invention comprises the following steps of:
1. coupling: coupling an electronic device with a circuit board such that a distinguishing resistor is coupled adjacent to a light-emitting diode;
2. baking: baking the circuit board by a reflow oven; and
3. testing: testing the baked circuit board.

In the practical manufacturing process, the electronic device is coupled with the circuit board by a dual in-line package (DIP) method. Alternatively, a layer of solder paste may be first spread on the circuit board, and then the electronic device is coupled with the circuit board by a surface mount technology (SMT) method. After the electronic device is coupled with the circuit board, the distinguishing resistor is coupled adjacent to the light-emitting diode. Next, the circuit board is baked by the high-temperature reflow oven. A lighting-up test, a stability test, and a function test are performed on the baked circuit board, respectively. The manufacturing process is completed if the circuit board passes these tests.

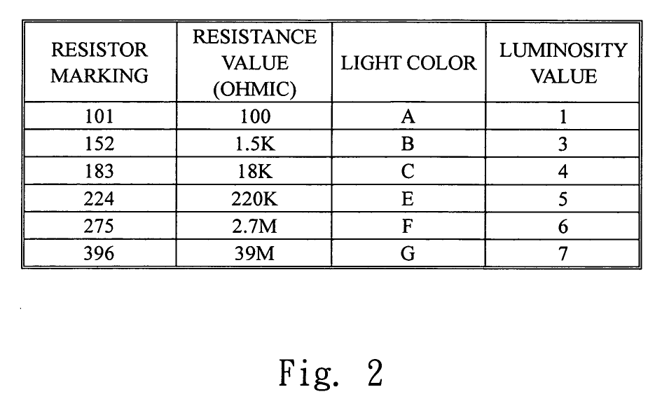

The distinguishing resistor is provided with a resistance value, which is marked on the distinguishing resistor by numeral symbols or traditional color bars comprising black, brown, red, orange, yellow, green, blue, violet, gray, or white bars, so as to know the light color and the luminosity value of the light-emitting diode easily by referring to a look-up table. Referring to FIG. 2, if the distinguishing resistor is, for example, marked with a reference number 183, the light-emitting diode has a resistance value of 18K and a luminosity value of 4 with C-grade light color.

The lighting-up test can be performed to verify whether the light color and the luminosity value of the light-emitting diode are consistent with the reference number marked on the distinguishing resistor so as to permit a detecting worker to perform the process of verification easily. The full-scale stability test and the localized function test are respectively performed so as to complete the manufacture of the circuit board. Moreover, after a long period of use, the distinguishing resistor of the present invention avoids the problem of peeling off as occurred in the conventional printed marking symbols or marking pasters. In addition, a manual verification process is performed individually when the distinguishing resistor is located on the circuit board that has no current loop formed thereon. Alternatively, the verification process can be performed automatically when the distinguishing resistor is located on the circuit board on which a current loop is formed thereon.

In summary, the present invention discloses an innovative manufacturing method for a light-emitting diode module so as to reduce the cost of marking by improving the deficiencies of the conventional marking method of the circuit board, which requires higher cost of marking and has easy-peeled marking. Accordingly, the present invention satisfies the patentability and is therefore submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A method of manufacturing a light-emitting diode module comprising the steps of:
coupling an electronic device with a circuit board such that a distinguishing resistor is coupled adjacent to a light-emitting diode;
baking the circuit board by a reflow oven; and
testing the baked circuit board, whereby the related information of the light-emitting diode can be obtained via the distinguishing resistor.

2. The method of manufacturing the light-emitting diode module of claim 1, wherein the distinguishing resistor has a resistance value marked thereon directly by numeral symbols.

3. The method of manufacturing the light-emitting diode module of claim 1, wherein the distinguishing resistor has a resistance value marked thereon by traditional color bars comprising black, brown, red, orange, yellow, green, blue, violet, gray, or white bars.

4. The method of manufacturing the light-emitting diode module of claim 1, wherein a lighting-up test, a stability test, and a function test are performed in the testing step.

5. The method of manufacturing the light-emitting diode module of claim 1, wherein the distinguishing resistor is verified individually and manually in the absence of a current loop.

6. The method of manufacturing the light-emitting diode module of claim 1, wherein the distinguishing resistor is verified automatically in the presence of a current loop.

7. The method of manufacturing the light-emitting diode module of claim 1, wherein the electronic device is coupled with the circuit board by a dual in-line package (DIP) method.

8. The method of manufacturing the light-emitting diode module of claim 1, wherein the electronic device is coupled with the circuit board by a surface mount technology (SMT) method
